(19) United States
(12) Patent Application Publication
(10) Pub. No.: US 2008/0009132 A1
(43) Pub. Date: Jan. 10, 2008

(54) Via hole forming method

(75) Inventor: Hiroshi Morikazu, Tokyo (JP)

Correspondence Address: SMITH, GAMBRELL & RUSSELL, 1130 CONNECTICUT AVENUE, N.W., SUITE 1130, WASHINGTON, DC, 20036, US

(73) Assignee: Disco Corporation

(21) Appl. No.: 11/808,385

(22) Filed: Jun. 8, 2007

(30) Foreign Application Priority Data
Jun. 27, 2006 (JP) 2006-176703

(51) Int. Cl. H01L 21/4763

(52) U.S. Cl. 438/637; 438/640

(57) ABSTRACT

A method of forming a via hole reaching a bonding pad in a wafer having a plurality of devices formed on the front surface of a substrate and bonding pads formed on each of the devices by applying a pulse laser beam to the rear surface of the substrate, the method comprising the steps of:
forming a non-through hole having a predetermined depth in the front surface of the substrate by applying a pulse laser beam having a spot diameter of 0.75 to 0.9 D when the diameter of the via hole to be formed is represented by D and an energy density per pulse of 40 to 60 J/cm² to the rear surface of the substrate; and
forming a via hole reaching a bonding pad in the substrate by applying a pulse laser beam having an energy density per pulse of 25 to 35 J/cm² to the hole formed in the substrate.

1. Field of the Invention

The present invention relates to a method of forming a via hole reaching a bonding pad in a wafer having a plurality of devices on the front surface of a substrate and bonding pads on each of the devices by applying a pulse laser beam to the rear surface of the substrate.

2. Description of the Prior Art

In the production process of a semiconductor device, a plurality of areas are defined by dividing lines called “streets” arranged in a lattice on the front surface of a substantially disk-like semiconductor wafer, and a device such as IC or LSI is formed in each of the defined areas. Individual semiconductor chips are manufactured by cutting this semiconductor wafer along the streets to divide it into the device formed areas.

To reduce the size and to increase the number of functions of an apparatus, a modular structure for connecting the bonding pads of a plurality of semiconductor chips which are formed in a layer has been implemented. As disclosed by JP-A 2003-163323, for example, this modular structure is such that a plurality of devices are formed on the front surface of a substrate constituting a semiconductor wafer, bonding pads are formed on each of the devices, via holes reaching the bonding pads are formed from the rear side of the substrate at positions where the bonding pads are formed, and a conductive material such as aluminum or copper for connecting the bonding pads is buried in the via holes.

The via holes formed in the above semiconductor wafer are generally formed by a drill. Therefore, the diameters of the via holes formed in the semiconductor wafer are as small as 100 to 300 μm, and drilling the via holes is not always satisfactory in terms of productivity. In addition, as the thickness of each of the above bonding pads is about 1 to 5 μm, in order to form the via holes only in the substrate such as a silicon substrate forming the wafer without damaging the bonding pads, the drill must be controlled extremely accurately.

To solve the above problem, the applicant of the present application proposes as Japanese Patent Application No. 2005-249643(JP-A 2007-67082) a method of efficiently forming a via hole reaching a bonding pad in a wafer having a plurality of devices on the front surface of a substrate and bonding pads on each of the devices by applying a pulse laser beam to the rear surface of the substrate.

Although a conductive material such as aluminum or copper is buried in the via holes formed in the substrate as described above, when aluminum or copper is directly buried in the via holes, aluminum or copper atoms diffuse into the inside of the substrate made of silicon to reduce the quality of each device. Therefore, after an insulating film is formed on the inner walls of the via holes, a conductive material such as aluminum or copper is buried.

Therefore, when the via holes are formed by applying a pulse laser beam as described above, the laser beam used to form the via holes in the substrate made of silicon is slightly applied to the rear surfaces of the bonding pads, whereby metal atoms forming the bonding pads are scattered to become metal contaminants which adhere to the inner walls of the via holes. When aluminum or copper atoms adhere to the inner walls of the via holes, the atoms diffuse into the inside of the substrate made of silicon to decrease the quality of each device.

### SUMMARY OF THE INVENTION

It is an object of the present invention to provide a via hole forming method which is capable of efficiently forming a via hole reaching a bonding pad without producing metal contaminants.

To attain the above object, according to the present invention, there is provided a method of forming a via hole reaching a bonding pad in a wafer having a plurality of devices on the front surface of a substrate and bonding pads on each of the devices by applying a pulse laser beam to the rear surface of the substrate, the method comprising the steps of:

forming an non-through hole having a predetermined depth in the front surface of the substrate by applying a pulse laser beam having a spot diameter of 0.75 to 0.9 D when the diameter of the via hole to be formed is represented by D and an energy density per pulse of 40 to 60 J/cm² to the rear surface of the substrate; and

forming a via hole reaching a bonding pad in the substrate by applying a pulse laser beam having the same spot diameter as in the first step and an energy density per pulse of 25 to 35 J/cm² to the hole formed in the substrate.

The above second step is preferably followed by a cleaning step for cleaning the inner wall of the via hole by carrying out trepanning for applying a pulse laser beam having a spot diameter of 0.2 to 0.3 D and an energy density per pulse of 3 to 20 J/cm² to the inner wall of the via hole formed in the substrate.

The inner wall of the via hole formed by the first step and the second step is tapered from the rear surface toward the front surface of the substrate and the cleaning step is to carry out trepanning for applying a pulse laser beam along the tapered surface.

In the via hole forming method of the present invention, as the pulse laser beam applied in the first step has an energy density (40 to 60 J/cm² per pulse) capable of processing a semiconductor substrate made of silicon efficiently, holes can be formed efficiently. The unprocessed portions formed in the first step are processed by applying a pulse laser beam having an energy density (25 to 35 J/cm² per pulse) which can process a semiconductor substrate made of silicon and the like but hardly processes a metal in the second step to form via holes reaching bonding pads. Therefore, in the via hole forming method of the present invention, via holes reaching bonding pads can be formed efficiently without producing metal contaminants.

### BRIEF DESCRIPTION OF THE DRAWINGS

FIG. 1 is a perspective view of a semiconductor wafer as a wafer to be processed by the via hole forming method of the present invention;

FIG. 2 is a perspective view of the key section of a laser beam machine for carrying out the via hole forming method of the present invention;

FIG. 3 is a diagram showing the first step in the via hole forming method of the present invention;

FIG. 4 is a partially enlarged sectional view of the semiconductor wafer having non-through holes which are formed by the first step in the via hole forming method of the present invention;

FIG. 5 is a partially enlarged sectional view of the semiconductor wafer having via holes which are formed by the second step in the via hole forming method of the present invention;

FIG. 6 is a block diagram of laser beam application means provided in the laser beam machine shown in FIG. 2;

FIG. 7 is a diagram showing trepanning which is carried out by the laser beam application means shown in FIG. 6; and

FIG. 8 is a diagram showing the cleaning step in the via hole forming method of the present invention.

### DETAILED DESCRIPTION OF THE PREFERRED EMBODIMENT

A preferred embodiment of the present invention will be described in detail hereinbelow with reference to the accompanying drawings.

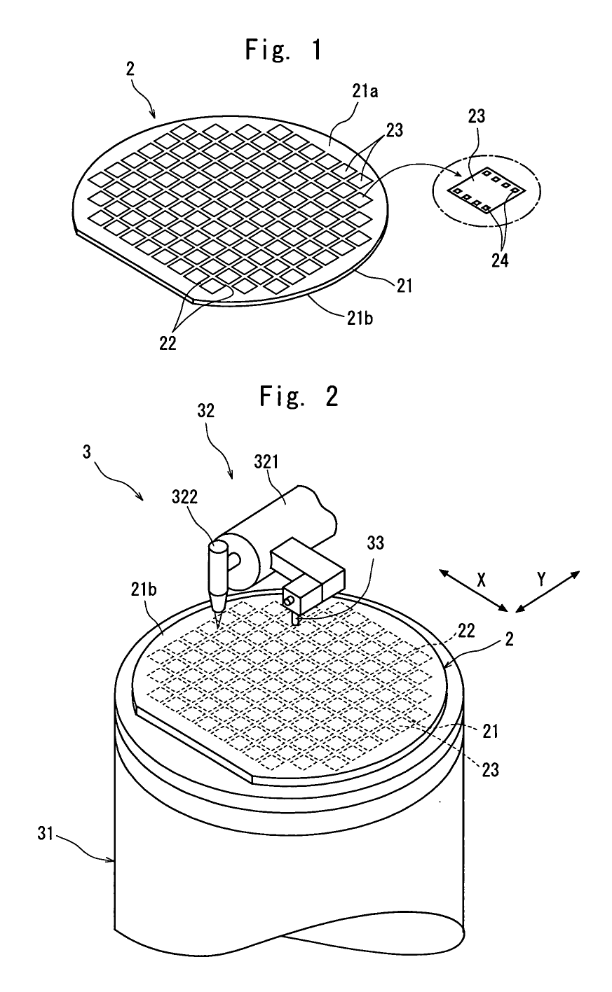

FIG. 1 is a perspective view of a semiconductor wafer 2 as the wafer to be processed by the via hole forming method of the present invention. In the semiconductor wafer 2 shown in FIG. 1, a plurality of areas are defined by a plurality of streets 22 arranged in a lattice on the front surface 21a of a substrate 21 made of silicon and having a thickness of, for example, 100 μm, and a device 23 such as IC or LSI is formed in each of the defined areas. The devices 23 are the same in structure. A plurality of bonding pads 24 are formed on the surface of each device 23. The bonding pads 24 are made of a metal material such as aluminum, copper, gold, platinum or nickel and have a thickness of 1 to 5 μm.

Via holes reaching the bonding pads 24 are formed in the above semiconductor wafer 2 by applying a pulse laser beam to the rear surface 21b of the substrate 21. To form the via holes in the substrate 21 of the semiconductor wafer 2, a laser beam machine 3 shown in FIG. 2 is used. The laser beam machine 3 shown in FIG. 2 comprises a chuck table 31 for holding a workpiece and laser beam application means 32 for applying a laser beam to the workpiece held on the chuck table 31. The chuck table 31 is designed to suction hold the workpiece and to be moved in a feed direction shown by an arrow X in FIG. 2 by an unshown feed mechanism and an indexing direction shown by an arrow Y by an unshown indexing mechanism.

The above laser beam application means 32 applies a pulse laser beam from a condenser 322 mounted to the end of a cylindrical casing 321 arranged substantially horizontally. The illustrated laser beam machine 3 comprises image pick-up means 33 mounted to the end portion of the casing 321 constituting the above laser beam application means 32. This image pick-up means 33 comprises infrared illuminating means for applying infrared radiation to the workpiece, an optical system for capturing infrared radiation applied by the infrared illuminating means, and an image pick-up device (infrared CCD) for outputting an electric signal corresponding to infrared radiation captured by the optical system, in addition to an ordinary image pick-up device (CCD) for picking up an image with visible radiation. An image signal is supplied to unshown control means.

A description is subsequently given of the method of forming via holes in the above semiconductor wafer 2 by using the above-described laser beam machine 3.

The front surface 2a of the semiconductor wafer 2 is first placed on the chuck table 31 of the laser beam machine 3 shown in FIG. 2, and the semiconductor wafer 2 is suction held on the chuck table 31. Therefore, the semiconductor wafer 2 is held in such a manner that the rear surface 21b faces up.

The chuck table 31 suction holding the semiconductor wafer 2 as described above is positioned right below the image pick-up means 33 by the unshown feed mechanism. After the chuck table 31 is positioned right below the image pick-up means 33, the semiconductor wafer 2 on the chuck table 31 is supposed to be located at a predetermined coordinate position. In this state, alignment work for checking whether the streets 22 formed in a lattice on the semiconductor wafer 2 held on the chuck table 31 are parallel to the X direction and the Y direction is carried out. That is, the image pick-up means 33 picks up an image of the semiconductor wafer 2 held on the chuck table 31 and carries out image processing such as pattern matching to perform the alignment work. Although the street 22 formed on the front surface 21a of the substrate 21 of the semiconductor wafer 2 faces down at this point, an image of the streets 22 can be picked up through the rear surface 21b of the substrate 21 as the image pick-up means 33 comprises infrared illuminating means, an optical system for capturing infrared radiation and an image pick-up device (infrared CCD) for outputting an electric signal corresponding to the infrared radiation as described above.

By carrying out the above-described alignment work, the semiconductor wafer 2 held on the chuck table 31 is located at the predetermined coordinate position. The designed coordinate positions of the plurality of bonding pads 24 formed on the devices 23 on the front surface 21a of the substrate 21 of the semiconductor wafer 2 are stored in the unshown control means of the laser beam machine 3 in advance.

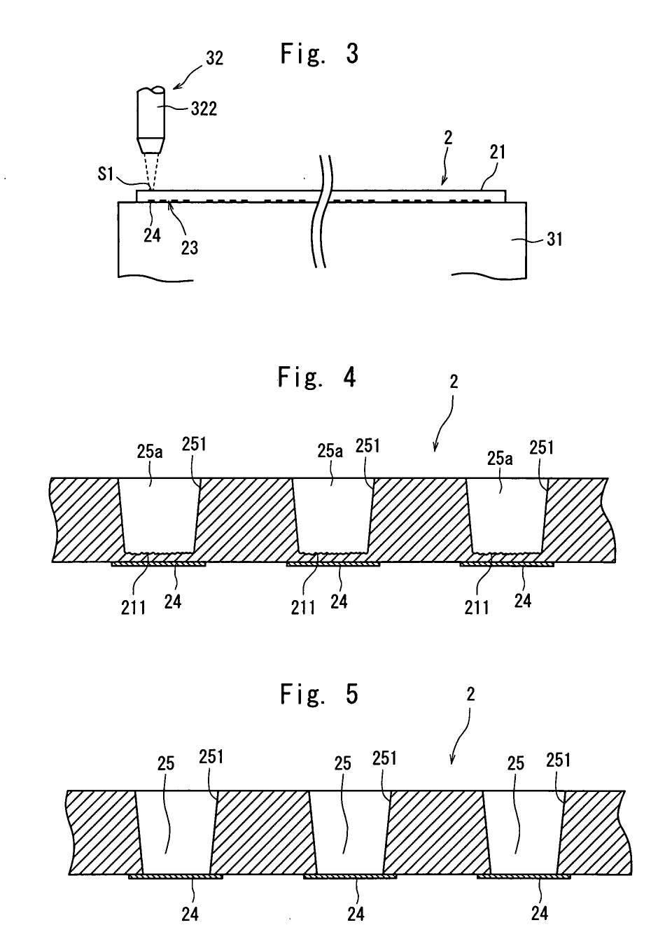

After the above alignment work is carried out, the chuck table 31 is moved as shown in FIG. 3 to position a device 23 at the most left end in FIG. 3 out of the plurality of devices 23 formed in a predetermined direction on the substrate 21 of the semiconductor wafer 2 right below the condenser 322. Then, a bonding pad 24 at the most left end out of the plurality of bonding pads 24 formed on the device 23 at the most left end in FIG. 3 is positioned right below the condenser 322.

Next comes the first step for forming non-through holes having a predetermined depth in the front surface of the substrate 21 by applying a pulse laser beam having a spot diameter of 0.75 to 0.9 D when the diameter of the via hole to be formed is represented by D and an energy density per pulse of 40 to 60 J/cm² to the rear surface of the substrate 21. That is, the energy density of the pulse laser beam applied from the condenser 322 of the laser beam application means 32 is set to a level (40 to 60 J/cm² per pulse) capable of processing a semiconductor substrate made of silicon and the like efficiently, and a predetermined number of pulses are applied to the rear surface 21b of the substrate 21.

The processing conditions in this first step are set as follows.

Light source of laser beam: YVO4 laser or YAG laser

### Wavelength: 355 nm

Energy density per pulse: 40 to 60 J/cm²
Spot diameter: 0.75 to 0.9 D when the diameter of a via hole to be formed is represented by D

Under the above processing conditions, when the substrate 21 of the semiconductor wafer 2 is made of silicon, as shown in FIG. 3, a hole having a depth of 3 μm can be formed with one pulse of the pulse laser beam by setting a spot S1 having the above spot diameter to the rear surface 21b (top surface) of the substrate 21. Therefore, by applying 30 pulses of the pulse laser beam, a non-through hole 25a having a depth of 90 μm is formed in the rear surface 21b of the substrate 21 as shown in FIG. 4. As a result, when the thickness of the substrate 21 made of silicon is 100 μm, an unprocessed portion 211 having a thickness of 10 μm remains on the front surface 21a side of the substrate 21. Since the energy density of the pulse laser beam applied in this first step is set to a level (40 to 60 J/cm² per pulse) capable of processing a semi-conductor substrate made of silicon efficiently, the holes 25a can be formed efficiently.

After the first step is carried out to form the holes 25a in the substrate 21 of the semiconductor wafer 2, next comes the second step for forming via holes reaching bonding pads 24 in the substrate 21 by applying a pulse laser beam having the same spot diameter as in the first step and an energy density per pulse of 25 to 35 J/cm² to the holes 25a formed in the substrate 21. That is, after the energy density of the pulse laser beam applied from the condenser 322 of the laser beam application means 32 is set to a level (25 to 35 J/cm² per pulse) which can process a semiconductor substrate made of silicon but hardly processes a metal, this pulse laser beam is applied to the holes 25a formed in the substrate 21.

The processing conditions in the second step are set as follows.

Light source of laser beam: YVO4 laser or YAG laser

### Wavelength: 355 nm

Energy density per pulse: 25 to 35 J/cm²
Spot diameter: 0.75 to 0.9 D when the diameter of a via hole to be formed is represented by D

Under the above processing conditions, when the substrate 21 of the semiconductor wafer 2 is made of silicon, as shown in FIG. 3, a hole having a depth of 2 μm can be formed with one pulse of the pulse laser beam by setting the spot S1 having the above spot diameter to the rear surface 21b (top surface) of the substrate 21. Therefore, by applying 5 pulses of the pulse laser beam, the unprocessed portion 211 below the hole 25a formed by the first step is processed to form a via hole 25 reaching the bonding pad 24 as shown in FIG. 5.

The inner wall 251 of the via hole 25 formed as described above is tapered from the rear surface 21b toward the front surface 21a of the substrate 21. When the thickness of the substrate 21 made of silicon is 100 μm and the diameter of the via hole 25 on the rear surface 21b side is 100 μm, the diameter of the via hole 25 on the front surface 21a side becomes about 60 μm.

When the above second step is carried out, the pulse laser beam used to form the via holes is slightly applied to the rear surfaces of the bonding pads 24. Although the energy density of the pulse laser beam applied in the second step is set to a level (25 to 35 J/cm² per pulse) which can process a semiconductor substrate made of silicon and the like but hardly processes a metal, metal atoms forming the bonding pads 24 are slightly scattered to become metal contaminants which may adhere to the tapered surface 251 which is the inner wall of the via hole 25 by electrostatic force. The metal contaminants adhering to the tapered surface 251 of the via hole 25 are desirably removed because they diffuse into the inside of the substrate 21 to decrease the quality of each device 23.

In this embodiment, a cleaning step for cleaning the tapered surface 251 of the via hole 25 by applying a pulse laser beam to the tapered surface 251 which is the inner wall of the via hole 25 formed in the substrate 21 is carried out in the second step. In this cleaning step, trepanning by applying a pulse laser beam along the tapered surface 251 is carried out.

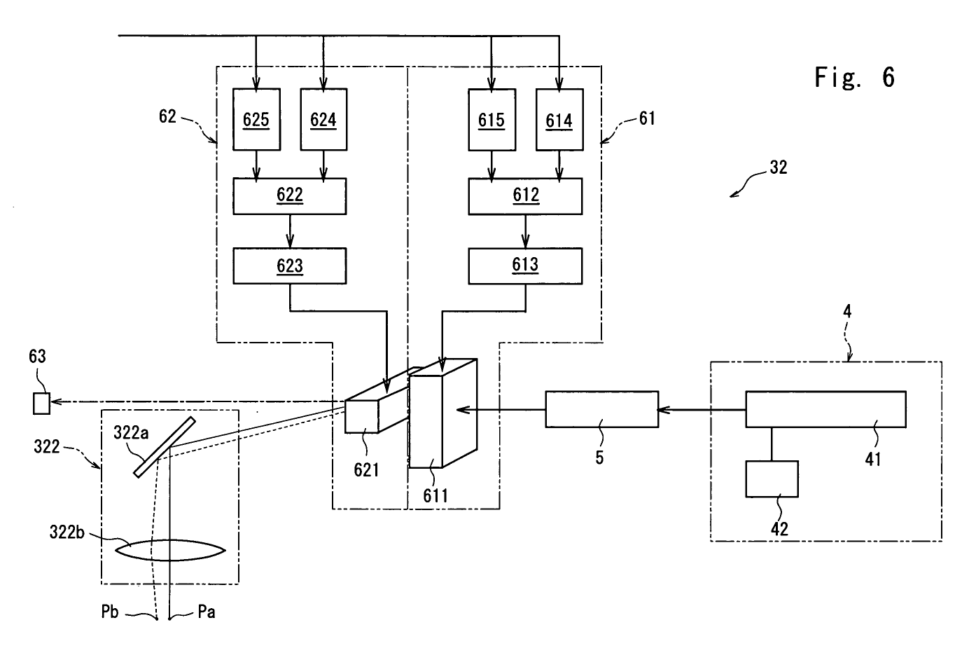

The laser beam application means 32 for carrying out trepanning will be described with reference to FIG. 6.

The laser beam application means 32 in the above laser beam machine 3 shown in FIG. 2 comprises pulse laser beam oscillation means 4, a transmission optical system 5, first acousto-optic deflection means 61 for deflecting the optical axis of a laser beam oscillated by the pulse laser beam oscillation means 4 in the feed direction (X direction) and second acousto-optic deflection means 62 for deflecting the optical axis of a laser beam oscillated by the pulse laser beam oscillation means 4 in the indexing direction (Y direction) all of which are installed in the above casing 321. The above condenser 322 includes a direction changing mirror 322a for changing the direction of a pulse laser beam passing through the above first acousto-optic deflection means 61 and the second acousto-optic deflection means 62 to a downward direction and a condenser lens 322b for converging the laser beam whose direction has been changed by the direction changing mirror 322a.

The above pulse laser beam oscillation means 4 comprises a pulse laser beam oscillator 41 and cyclic frequency setting means 42 connected to the pulse laser beam oscillator 41. The above transmission optical system 5 includes a suitable optical element such as a beam splitter.

The above first acousto-optic deflection means 61 comprises a first acousto-optic device 611 for deflecting the optical axis of a laser beam oscillated by the pulse laser beam oscillation means 4 in the feed direction (X direction), a first RF oscillator 612 for generating RF (radio frequency) to be applied to the first acousto-optic device 611, a first RF amplifier 613 for amplifying the power of RF generated by the first RF oscillator 612 to apply it to the first acousto-optic device 611, first deflection angle control means 614 for controlling the frequency of RF generated by the first RF oscillator 612, and first output control means 615 for controlling the amplitude of RF generated by the first RF oscillator 612. The above first acousto-optic device 611 can control the deflection angle of the optical axis of a laser beam according to the frequency of the applied RF and the output of a laser beam according to the amplitude of the applied RF. The first deflection angle control means 614 and the first output control means 615 are controlled by the unshown control means.

The above second acousto-optic deflection means 62 comprises a second acousto-optic device 621 for deflecting the optical axis of a laser beam oscillated by the pulse laser beam oscillation means 4 in the indexing direction (Y direction) perpendicular to the feed direction (X direction), a second RF oscillator 622 for generating RF to be applied to the second acousto-optic device 621, a second RF amplifier 623 for amplifying the power of RF generated by the second RF oscillator 622 to apply it to the second acousto-optic device 621, second deflection angle control means 624 for controlling the frequency of RF generated by the second RF oscillator 622, and second output control means 625 for controlling the amplitude of RF generated by the second RF oscillator 622. The above second acousto-optic device 621 can control the deflection angle of the optical axis of a laser beam according to the frequency of the applied RF and the output of a laser beam according to the amplitude of the applied RF. The above second deflection angle control means 624 and the second output control means 625 are controlled by the unshown control means.

The laser beam application means 32 in the illustrated embodiment comprises laser beam absorbing means 63 for absorbing a laser beam not deflected by the first acousto-optic device 611 as shown by a one-dot chain line in FIG. 6 when RF is not applied to the above first acousto-optic device 611.

The laser beam application means 32 in the illustrated embodiment is constituted as described above. When RF is not applied to the first acousto-optic device 611 and the second acousto-optic device 621, a pulse laser beam oscillated by the pulse laser beam oscillation means 4 is guided to the laser beam absorbing means 63 through the transmission optical system 5, the first acousto-optic device 611 and the second acousto-optic device 621 as shown by the one-dot chain line in FIG. 6. Meanwhile, when RF having a frequency of, for example, 10 kHz is applied to the first acousto-optic device 611, the optical axis of a pulse laser beam oscillated by the pulse laser beam oscillation means 4 is deflected and focused at a focal point Pa as shown by the solid line in FIG. 6. When RF having a frequency of, for example, 20 kHz is applied to the first acousto-optic device 611, the optical axis of a pulse laser beam oscillated by the pulse laser beam oscillation means 4 is deflected and focused at a focal point Pb which shifts from the above focal point Pa by a predetermined distance in the feed direction (X direction) as shown by the broken line in FIG. 6. When RF having a predetermined frequency is applied to the second acousto-optic device 621, the optical axis of a pulse laser beam oscillated by the pulse laser beam oscillation means 4 is focused at a focal point which shifts from the above focal point Pa by a predetermined distance in the indexing direction (Y direction, direction perpendicular to the sheet in FIG. 6) perpendicular to the feed direction (X direction).

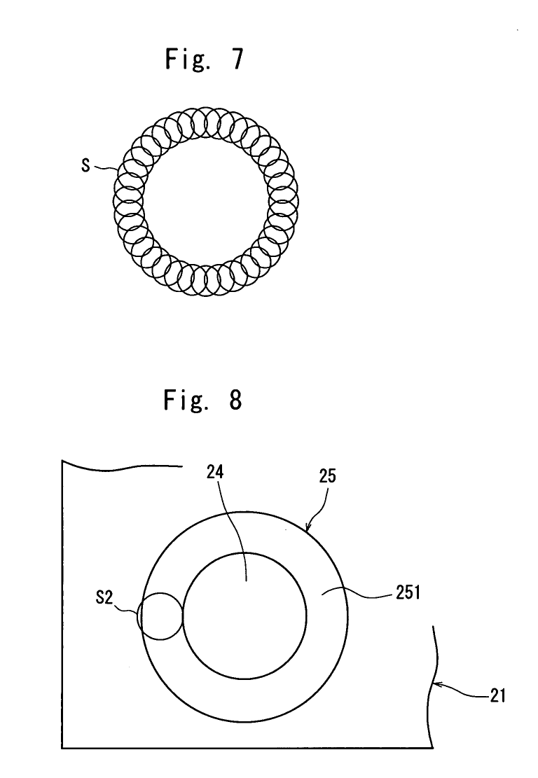

Therefore, trepanning for moving the spot S of a pulse laser beam in a loop as shown in FIG. 7 can be carried out by activating the first acousto-optic deflection means 61 and the second acousto-optic deflecting means 62 to deflect the optical axis of the pulse laser beam in the X direction and Y direction sequentially.

The processing conditions in the cleaning step which is carried out by using the above laser beam application means 32 are set as follows.

Light source of laser beam: YVO4 laser or YAG laser

### Wavelength: 355 nm

Energy density per pulse: 3 to 20 J/cm²
Spot diameter: 0.2 to 0.3 D when the diameter of a via hole to be formed is represented by D

To carry out the cleaning step under the above processing conditions, as shown in FIG. 8, the spot S2 of a pulse laser beam applied from the condenser 322 of the above laser beam application means 32 is controlled to be set to the tapered surface 251 which is the inner wall of the via hole 25 formed in the substrate 21. The laser beam application means 32 and the chuck table 36 are then activated to carry out trepanning as shown in FIG. 7. It is important that the center (the position of the peak of a Gaussian distribution) of the spot S2 of the pulse laser beam should not be applied to the bonding pad 24 at this point. As a result, the pulse laser beam is applied along the tapered surface 251 which is the inner wall of the via hole 25 formed in the substrate 21 to remove a trace amount of the metal contaminants adhering to the tapered surface 251 by electrostatic force. Since the energy density of the pulse laser beam applied in this cleaning step is small, the substrate 21 is not processed.

What is claimed is:

1. A method of forming a via hole reaching a bonding pad in a wafer having a plurality of devices on the front surface of a substrate and bonding pads on each of the devices by applying a pulse laser beam to the rear surface of the substrate, the method comprising the steps of:
forming a non-through hole having a predetermined depth in the front surface of the substrate by applying a pulse laser beam having a spot diameter of 0.75 to 0.9 D when the diameter of the via hole to be formed is represented by D and an energy density per pulse of 40 to 60 J/cm² to the rear surface of the substrate; and
forming a via hole reaching a bonding pad in the substrate by applying a pulse laser beam having the same spot diameter as in the first step and an energy density per pulse of 25 to 35 J/cm² to the hole formed in the substrate.

2. The via hole forming method according to claim 1, wherein the second step is followed by a cleaning step for cleaning the inner wall of the via hole by carrying out trepanning for applying a pulse laser beam having a spot diameter of 0.2 to 0.3 D and an energy density per pulse of 3 to 20 J/cm² to the inner wall of the via hole formed in the substrate.

3. The via hole forming method according to claim 1 or 2, wherein the inner wall of the via hole formed by the first step and the second step is tapered from the rear surface toward the front surface of the substrate and the cleaning step is to carry out trepanning for applying a pulse laser beam along the tapered surface.
